(19) United States
(12) Patent Application Publication
(10) Pub. No.: US 2009/0190054 A1
(43) Pub. Date: Jul. 30, 2009

(54) Display Substrate, Method Of Manufacturing The Same And Liquid Crystal Display Panel Having The Display Substrate

(76) Inventors: Yong-Jo KIM, Gwangmyeong-si (KR); Jang-Soo Kim, Yongin-si (KR); Byoung-Joo Kim, Anyang-si (KR); Kweon-Sam Hong, Seoul (KR); Jae-Hyoung Youn, Seoul (KR); Yui-Ku Lee, Gwangmyeong-si (KR); Sahng-Ik Jun, Yongin-si (KR); Woo-Sung Sohn, Seoul (KR); Jin-Seuk Kim, Daedeok-gu (KR)

Correspondence Address: Haynes and Boone, LLP;IP Section, 2323 Victory Avenue, SUITE 700, Dallas, TX, 75219, US

(21) Appl. No.: 12/336,447

(22) Filed: Dec. 16, 2008

(30) Foreign Application Priority Data
Jan. 28, 2008 (KR) 10-2008-0008344

(51) Int. Cl. G02F 1/1368; H01L 21/84

(52) U.S. Cl. 349/42; 438/30; 257/E21.7; 257/72

(57) ABSTRACT

A display substrate includes a plurality of transistors, a plurality of color filters, a plurality of pixel electrodes, a plurality of supporting members, and a plurality of filling members. The transistors are connected to a plurality of gate lines extending in a first direction on a base substrate and a plurality of data lines extending in a second direction crossing the first direction. The color filters are disposed over the transistors, and have a plurality of holes. The pixel electrodes are disposed on the color filters, and electrically connect to the transistors. The supporting members are disposed on the color filters, and maintain a gap between the base substrate and a substrate opposing the base substrate. The filling members are comprised of the same material as the supporting members, and fill the holes.

### CROSS-REFERENCE TO RELATED APPLICATIONS

This application claims priority under 35 U.S.C. §119 to Korean Patent Application No. 2008-8344, filed on Jan. 28, 2008 in the Korean Intellectual Property Office (KIPO), the contents of which are herein incorporated by reference in their entirety.

### BACKGROUND OF THE INVENTION

1. Field of the Invention

The present invention relates to a display substrate, a method of manufacturing the display substrate, and a liquid crystal display (LCD) panel having the display substrate.

2. Description of the Related Art

Generally, a liquid crystal display (LCD) panel includes an array substrate in which a plurality of thin-film transistors (TFTs) is arrayed, a color filter substrate opposing the array substrate and having the color filter, and a liquid crystal layer disposed between the array substrate and the color filter substrate.

Recently, a color filter on array (COA) substrate has been used. The COA substrate includes the color filter formed on the array substrate in which the TFTs are arrayed so that the COA substrate has an aperture ratio of the LCD panel may be improved. The COA substrate includes a TFT layer disposed on the base substrate, a color filter layer disposed on the TFT layer and having a contact hole, and a pixel electrode connected to a TFT including the TFT layer through the contact hole. The opposing substrate opposing the COA substrate has a common electrode corresponding to the pixel electrode.

Liquid crystal is dropped on a plurality of areas of the COA substrate to form the liquid crystal layer. When the liquid crystal layer is formed on the COA substrate, a sealing member is formed on a peripheral area of the COA substrate to couple the COA substrate with the opposing substrate. Thus, the liquid crystal layer is disposed between the COA substrate and the opposing substrate.

In reliability testing, the LCD panel using the COA substrate of high aperture ratio has liquid crystal filling defects, that is, active unfilled areas (AUAs) where voids are formed in the liquid crystal, may be formed when exposed to vibrations and high temperature. Thus, the LCD panel using the COA substrate may have the liquid crystal filling defects in a display area.

### SUMMARY OF THE INVENTION

The present invention provides a display substrate with an improved quality of liquid crystal filling.

The present invention further provides a method of manufacturing the display substrate.

The present invention further provides a liquid crystal display (LCD) panel having the above-mentioned display substrate.

In one aspect of the present invention, a display substrate includes a plurality of transistors, a plurality of color filters, a plurality of pixel electrodes, a plurality of supporting members, and a plurality of filling members. The transistors are connected to a plurality of gate lines extending in a first direction on a base substrate and a plurality of data lines extending in a second direction crossing the first direction. The color filters are disposed over the transistors, and have a plurality of holes. The pixel electrodes are disposed on the color filters, and electrically connect to the transistors. The supporting members are disposed on the color filters, and maintain a gap between the base substrate and a substrate opposing the base substrate. The filling members comprise the same material as the supporting members, and fill into the holes.

In another aspect of the present invention, there is provided a method of manufacturing a display substrate. In the method, a plurality of transistors that is connected to a plurality of gate lines extending in a first direction and a plurality of data lines extending to a second direction crossing the first direction is formed on a base substrate. A plurality of color filters having a plurality of holes on the base substrate formed the transistors is formed in the base substrate having the transistors. A plurality of pixel electrodes electrically connected to the transistors is formed on the base substrate having the color filters formed thereon. A plurality of supporting members and a plurality of filling members are formed on the color filters, and the supporting members maintain a gap between the base substrate and a substrate opposite to the base substrate and the filling members fill the holes.

In the other aspect of the present invention, an LCD panel includes a first display substrate and a second display substrate. The first display substrate includes a plurality of transistors connected to a plurality of gate lines extending in a first direction on a base substrate and a plurality of data lines extending in a second direction crossing the first direction, a plurality of color filters disposed over the transistors, having a plurality of holes, a plurality of pixel electrodes disposed on the color filters, a plurality of supporting members disposed on the color filters, and a plurality of filling members comprising the same material as the supporting members, to fill the holes. The second display substrate is coupled with the first display substrate to receive a liquid crystal layer, and the second display substrate is spaced apart from the first display substrate by the supporting member.

According to embodiments of the present invention, a filling member fills holes of a color filter so that the quality of liquid crystal filling may be improved. A supporting member is formed on a flat area so that compression characteristics of the supporting member may be improved. Thus, the quality of liquid crystal filling may be improved. In addition, an empty space of the peripheral is filled by the dam member to compensate a volume of the liquid crystal layer of the display area, so that the quality of liquid crystal filling may be improved.

### BRIEF DESCRIPTION OF THE DRAWINGS

The above and other features and advantages of the present invention will become more apparent by describing in detail embodiments thereof with reference to the accompanying drawings, in which:

FIG. 1 is a plan view illustrating a display panel according to a first embodiment of the present invention;

FIG. 2 is a cross-sectional view taken along a line I-I′ in FIG. 1;

FIGS. 3A and 3B are a cross-sectional view taken along a peripheral area in FIG. 1;

FIGS. 4A to 4C are cross-sectional views illustrating a method for manufacturing the display panel in FIG. 2;

FIG. 5 is a plan view illustrating a display panel according to a second embodiment of the present invention;

FIG. 6 is a cross-sectional view taken along a line II-II′ in FIG. 5;

FIGS. 7A to 7D are cross-sectional views illustrating a method for manufacturing the display panel in FIG. 6;

FIGS. 8A and 8B are plan views of color filter mask in FIGS. 7A and 7B;

FIGS. 9A to 9C are cross-sectional views illustrating a method for manufacturing a display substrate according to a third embodiment of the present invention; and

FIGS. 10A and 10B are plan views of color filter mask in FIGS. 9A and 9B.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

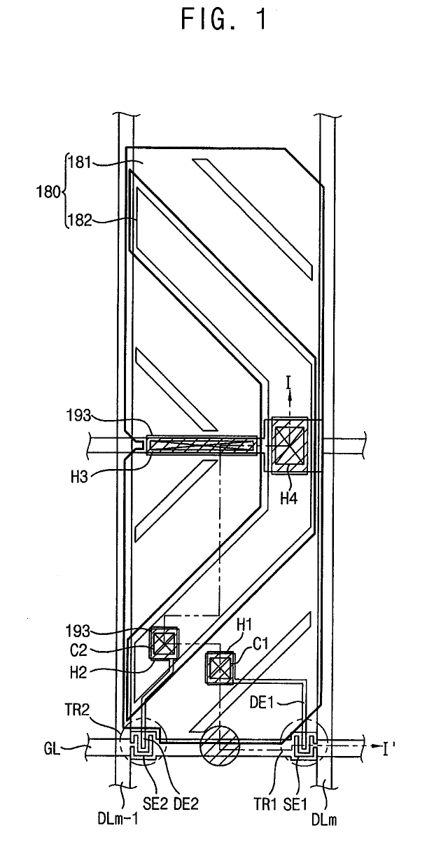

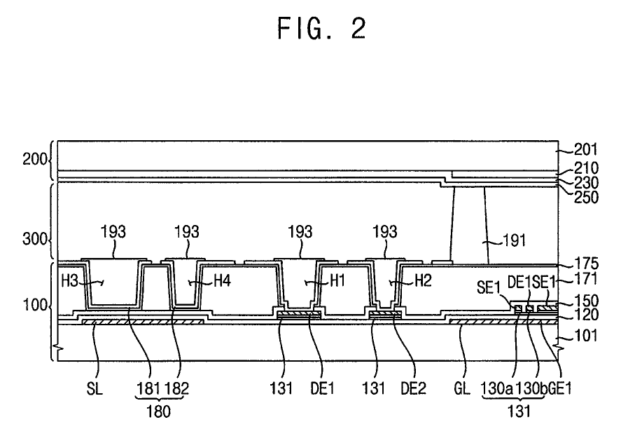

FIG. 1 is a plan view illustrating a display panel according to a first embodiment of the present invention. FIG. 2 is a cross-sectional view taken along a line I-I′ in FIG. 1.

Referring to FIGS. 1 and 2, a display panel includes a first display substrate 100, a second display substrate 200 and a liquid crystal layer 300. The liquid crystal layer 300 includes liquid crystal.

The first display substrate 100 includes a first base substrate 101, a plurality of transistors TR1 and TR2, a color filter 171, a pixel electrode 180, a supporting member 191 and a filling member 193.

A first metal pattern, a gate insulation layer 120, a channel pattern 131, a second metal pattern and a protective layer 150 are formed on the first base substrate 101. The first metal pattern includes a plurality of gate lines GL, a plurality of gate electrodes GE1 and GE2, and a storage line SL. Each of the gate lines GL is extended in a first direction. The gate electrodes GE1 and GE2 are defined on the gate line GL. The gate electrode GE1 of a first transistor TR1 and the gate electrode GE2 of a second transistor TR2 are defined on the gate line GL, respectively. The storage line SL may be formed parallel to the gate line GL as shown.

The gate insulation layer 120 is formed on the first base substrate 101 having the first metal pattern formed thereon. The channel pattern 131 is formed on the gate electrode GE1 of the first transistor TR1 and includes an active layer 130a and an ohmic contact layer 130b. The channel pattern may be formed on the gate electrode GE2 of the second transistor TR2.

The second metal pattern includes a plurality of data lines DLm−1 and DLm, a plurality of source electrodes SE1 and SE2, and a plurality of drain electrodes DE1 and DE2. The data lines DLm−1 and DLm are extended in a second direction crossing the first direction. The source electrodes SE1 and SE2 are extended from the data lines DLm−1 and DLm to overlap with the gate electrodes GE1 and GE2, respectively. The drain electrodes DE1 and DE2 are apart from the source electrodes SE1 and SE2 to overlap with the gate electrodes GE1 and GE2, respectively. First and second contact holes C1 and C2 are formed on ends of the drain electrodes DE1 and DE2 so that the pixel electrode 180 is electrically connected to the drain electrodes DE1 and DE2 through the first and second contact holes C1 and C2.

The protective layer 150 is formed on the first base substrate 101 having the second metal pattern formed thereon. The protective layer 150 protects the channel pattern 131 exposed between the source electrodes SE1 and SE2 and the drain electrodes DE1 and DE2 of the first and second transistors TR1 and TR2 from the exterior.

The color filter 171 is formed on a pixel area P of the first base substrate 101 in which the first and second transistors TR1 and TR2 are formed. The color filter 171 has first and second holes H1 and H2 corresponding to the first and second contact holes C1 and C2, and third and fourth holes H3 and H4 corresponding to an area in which the storage line SL is formed.

A capping layer 175 may be formed on the first base substrate 101 having the color filter 171 formed thereon, so that the capping layer 175 covers the color filter 171. The capping layer 175 blocks impurity ions from entering the liquid crystal layer 300. The impurity ions may be generated from the color filter 171.

The pixel electrode 180 is formed on the pixel area P, and the pixel electrode 180 is divided into a first sub-electrode 181 and a second sub-electrode 182 so that the first and second sub-electrodes 181 and 182 divide the liquid crystal layer 300 into multiple domains. The first and second sub-electrodes 181 and 182 may be patterned to have a chevron shape. The first sub-electrode 181 is electrically connected to the drain electrode DE1 of the first transistor TR1 through the first contact hole C1. The second sub-electrode 182 is electrically connected to the drain electrode DE2 of the second transistor TR2 through the second contact hole C2.

The first sub-electrode 181 contacts the capping layer 175 on the storage line SL through the third hole H3, and the second sub-electrode 182 contacts to the capping layer 175 on the storage line SL through the fourth hole H4. A first storage capacitor is defined by the storage line SL and the first sub-electrode 181 formed at an area in which the third hole H3 is formed, and a second storage capacitor is defined by the storage line SL and the second sub-electrode 182 formed at an area in which the fourth hole H4 is formed.

The supporting member 191 is formed on the gate line GL to maintain a gap between the first display substrate 100 and the second display substrate 200. The supporting member 191 is formed on the flat area in which the gate line GL is formed, so that a cell gap of the liquid crystal layer 300 may be uniformity maintained. Thus, the liquid crystal may easily fill the cell gap to form the secure liquid crystal layer 300 having high step coverage.

The filling member 193 is formed of the same material as the supporting member 191 and fills each of the first, second, third and fourth holes H1, H2, H3 and H4. The holes of the first display substrate 100 are filled with the filling member 193 so that the filling member 193 prevents the liquid crystal layer 300 from forming an empty space. Thus, the quality of liquid crystal filling may be improved. In addition, the filling member may improve adhesion between the color filter 171 and the capping layer 175.

The liquid crystal is dropped on the first display substrate 100 so that the liquid crystal layer 300 is formed on the first display substrate 100.

The second display substrate 200 includes a second base substrate 201, a blocking pattern 210, an overcoat layer 230 and a common electrode 250.

The blocking pattern 210 blocks light, and the blocking pattern 210 is formed on an area in which the pixel electrode 180 is not formed. The blocking pattern 210 is formed on areas corresponding to areas that the gate line GL, the data lines DL1 and DL2, and the transistors TR1 and TR2 are formed. The overcoat layer 230 is formed on the second base substrate 201 having the blocking pattern 210 formed thereon to flatten the second display substrate 200. The common electrode 250 is formed on the overcoat layer 230. The common electrode 250 includes an opening of the chevron shape to divide the liquid crystal layer 300 into multiple domains.

Here, the supporting member 191 for maintaining the gap between the first and second display substrates 100 and 200 is formed on the first display substrate 100. However, the supporting member 191 may be formed on the second display substrate 200. For example, the supporting member 191 may be formed in an area in which the overcoat layer 230 or the common electrode 250 of the second display substrate 200 is formed corresponding to the gate line GL.

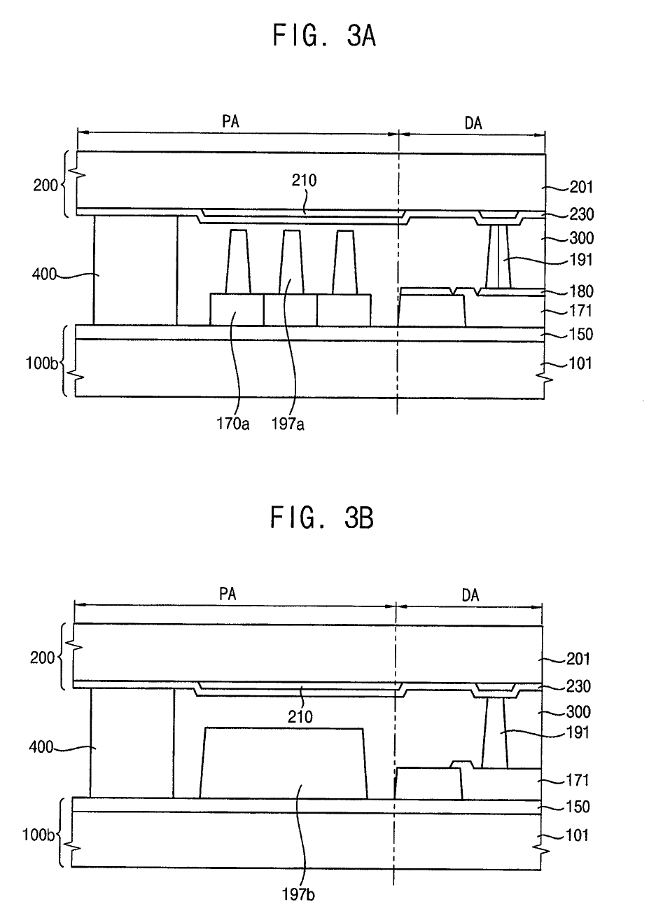

FIGS. 3A and 3B are a cross-sectional view taken along a peripheral area in FIG. 1.

Referring to FIG. 3A, the display panel includes a display area DA formed over the pixel electrode 180 and outside a peripheral area PA surrounding the display area.

The display area DA includes a plurality of pixel areas P as shown in FIGS. 1 and 2. A sealing member 400, a dummy color filter 170a and a dam member 197a are formed on the peripheral area of the first display substrate 100.

The sealing member 400 couples the first and second display substrates 100 and 200. The sealing member 400 may be formed on a gate driving circuit outputting a gate signal into the gate line GL. The gate driving circuit is integrated in the peripheral area PA of the first display substrate 100. The sealing member 400 may prevent corrosion of the gate driving circuit.

The dummy color filter 170a is formed of the same material as the color filter 171 of the display area DA. The dam member 197a is formed of the same material as the supporting member 191 and the filling member 193 of the display area DA. The dam member 197a is formed on the peripheral area PA having substantially the same shape as the supporting member 191. Alternatively, a plurality of the dam members 197a may be formed in the peripheral area PA.

The dummy color filter 170a and the dam member 197a are formed in the peripheral area PA to reduce the total volume of liquid crystal layer 300.

An empty space between the sealing member 400 and the display area DA is filled with the dummy color filter 170a and the dam member 197a so that the volume of the liquid crystal layer 300 disposed in the display area DA may be compensated. Thus, the quality of liquid crystal filling in a display area DA may be improved.

Referring to FIG. 3B, a dam member 197b formed on the peripheral area PA of the first display substrate 100 may be integrated into one body. In addition, the dummy color filter 170a may not be formed in the peripheral area PA of the first display substrate 100.

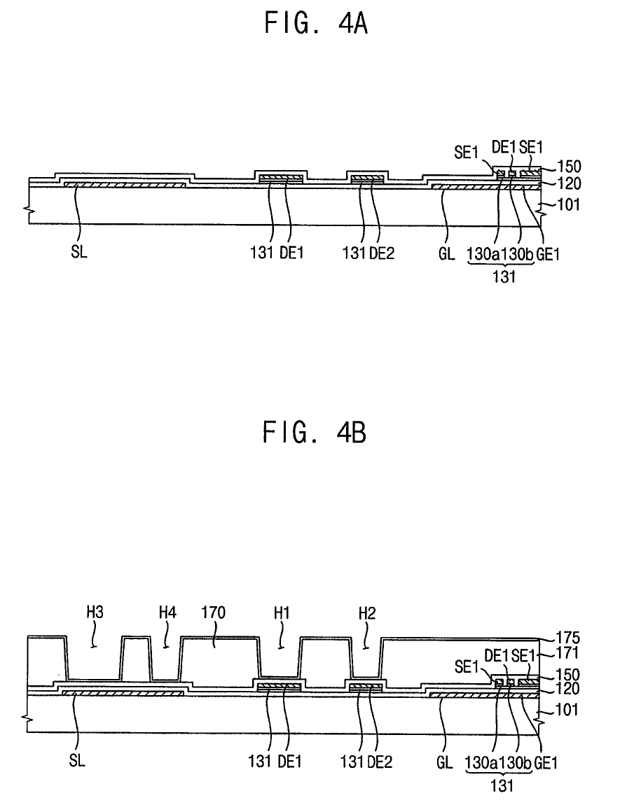

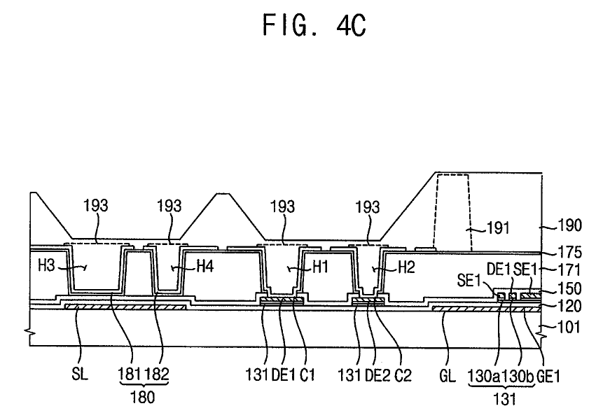

FIGS. 4A to 4C are cross-sectional views illustrating a method for manufacturing the display panel in FIG. 2.

Referring to FIGS. 1 and 4A, a first metal layer is formed on the first base substrate 101. The first metal layer is patterned by using a photoresist pattern to form the first metal pattern. The first metal pattern includes the gate line GL, the gate electrodes GE1 and GE2 of the first and second transistors TR1 and TR2, and the storage line SL.

The gate insulation layer 120 is formed on the first base substrate 101 having the first metal pattern formed thereon. A channel layer is formed on the first base substrate 101 having the gate insulation layer 120 formed thereon, and the channel layer includes the active layer 130a and the ohmic contact layer 130b.

A second metal layer is formed on the first base substrate 101 having the channel layer formed thereon. The second metal layer and the channel layer are patterned by using a photoresist pattern to form a second metal pattern. The second metal pattern includes the data lines DL1 and DL2, the source electrodes SE1 and SE2, and the drain electrodes DE1 and DE2.

Here, the second metal layer and the channel layer are patterned by using one photoresist pattern, but each of the second metal layer and the channel layers may be patterned by using different photoresist patterns. In one case, the channel pattern is formed on each of the gate electrodes GE1 and GE2 of the first and second transistors TR1 and TR2.

The protective layer 150 is formed on the first base substrate 101 having the second metal pattern formed thereon. Thus, the first and second transistors TR1 and TR2 are formed on the first base substrate 101.

Referring to FIGS. 1 and 4B, the color filter 171 is formed on the first base substrate 101 having the transistors TR1 and TR2 formed thereon. The dummy color filter 170a may be formed on the peripheral area PA as shown FIG. 3A.

The color filter 171 has a plurality of holes H1, H2, H3 and H4.

A first hole H1 is formed on the drain electrode DE1 of the first transistor TR1, and a second hole H2 is formed on the drain electrode DE2 of the second transistor TR2. The third hole H3 is formed on a first region of the storage line SL, and the fourth hole H4 is formed on a second region of the storage line SL. The protective layer 150 is exposed by the first, second, third and fourth holes H1, H2, H3 and H4.

The capping layer 175 may be formed on the color filter 171. The capping layer 175 blocks impurity ions from entering the liquid crystal layer 300. The impurity ions may be generated from the color filter 171.

Referring to FIGS. 1 and 4C, the capping layer 175 and the protective layer 180 are etched by using the photoresist pattern to form first and second contact holes C1 and C2. The first contact hole C1 exposes an end of the drain electrode DE1 of the transistor TR1, and the second contact hole C2 exposes an end of the drain electrode DE2 of the transistor TR2.

A transparent conductive layer is formed on the base substrate 101 having the first and second contact holes C1 and C2 formed thereon. The transparent conductive layer is patterned by using the photoresist pattern to form the pixel electrode 180 on pixel area P. The pixel electrode 180 includes the first sub-electrode 181 and the second sub-electrode 182. For example, the pixel electrode 180 is divided into the first and second sub-electrodes 181 and 182. The first sub-electrode 181 is connected to the drain electrode DE1 of the first transistor TR1 through the first contact hole C1, and the second sub-electrode 182 is connected to the drain electrode DE2 of the second transistor TR2 through the second contact hole C2.

In addition, the first sub-electrode 181 is connected to the capping layer 175 corresponding to the first region of the storage line SL through the third hole H3, and the second sub-electrode 182 is connected to the capping layer 175 corresponding to the second region of the storage line SL through the fourth hole H4.

A photosensitive organic layer 190 is formed on the first base substrate 101 having the pixel electrode 180 formed thereon. The photosensitive organic layer 190 is patterned to form the supporting member 191 and the filling member 193. In addition, the dam member 197a or 197b may be formed on the peripheral area by using the photosensitive organic layer 190 as shown in FIG. 3A or 3B.

The supporting member 191 is formed on a flat area corresponding to the gate line GL. The filling member 193 fills each of the holes H1, H2, H3 and H4 of the color filter 171. Thus, the holes H1, H2, H3 and H4 of the first display substrate 100 may be filled with the filling member 193.

Hereinafter, the same reference numerals will be used to refer to the same or like parts as those described in the first embodiment and any further repetitive explanation concerning the above elements will be simply described.

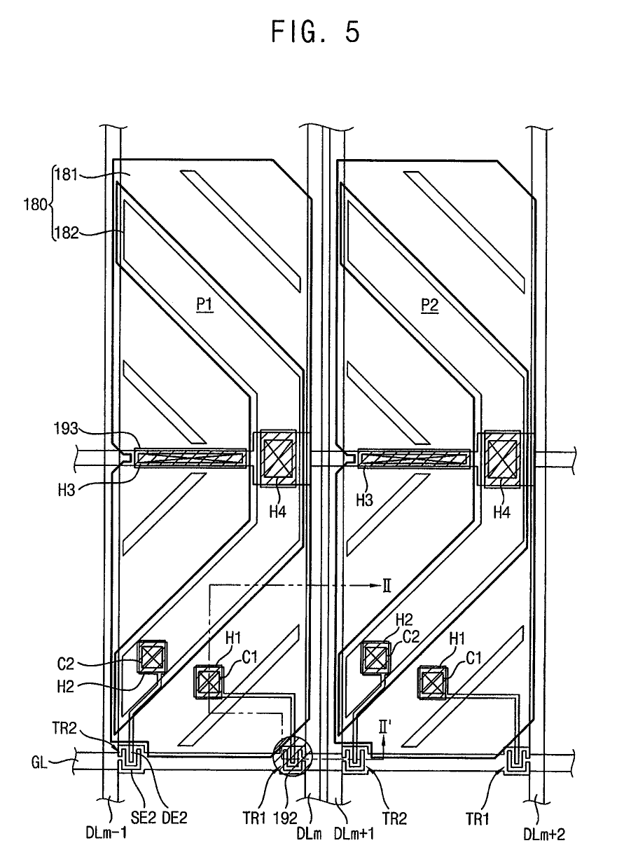

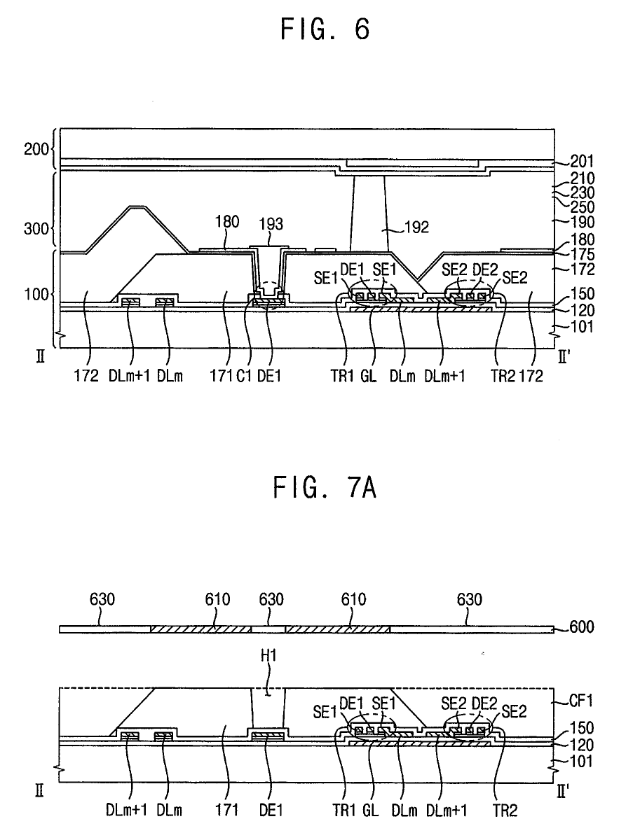

FIG. 5 is a plan view illustrating a display panel according to a second embodiment of the present invention. FIG. 6 is a cross-sectional view taken along a line II-II′ in FIG. 5.

Referring to FIGS. 5 and 6, a display panel includes a first display substrate 100, a second display substrate 200 and a liquid crystal layer 300.

The first display substrate 100 includes a first base substrate 101, a gate line GL extended in a first direction on the first base substrate 101, a plurality of data lines DLm−1, DLm, DLm+1 and DLm+2 extended in a second direction crossing the first direction, a plurality of transistors TR1 and TR2, a storage line SL, a gate insulation layer 120, a protective layer 150, a first color filter 171, a second color filter 172, a pixel electrode 180, a supporting member 192 and a filling member 193.

For example, first and second transistors TR1 and TR2 are formed on an area of a first pixel area P1 in which the gate line GL crosses (m−1)th and (m)th data lines DLm−1 and DLm. First and second transistors TR1 and TR2 are formed on an area of a second pixel area P2 in which the gate line GL crosses (m+1)th and (m+2)th data lines DLm+1 and DLm+2. The second pixel area P2 is adjacent to the first pixel area P1 toward the first direction.

The first color filter 171 is formed in the first pixel area P1. The second color filter 172 is formed in the second pixel area P2. One of the first and second color filters 171 and 172 formed after according to a sequence process covers or overlaps a portion of the other of the first and second color filters 171 and 172 formed before according to the sequence process, on a boundary area of the first and second pixel areas P1 and P2. For example, an end of the second color filter 172 covers an end of the first color filter 171 in the boundary area of the first and second pixel areas P1 and P2.

Ends of the first and second color filters 171 and 172 contact each other, and the ends are adjacent to the first transistor TR1 of the first pixel area P1. Adjacent sides of the first and second color filters 171 and 172 form the same boundary, wherein the sides are adjacent to the first transistor TR1. As shown, an end of the second color filter 172 formed after first color filter 171 according to the sequence process contacts an end of the first color filter 171 formed before second color filter 172 according to the sequence process. Thus, the first color filter 171 formed on the first transistor TR1 of the first pixel area P1 and the second color filter 172 formed on the second transistor TR2 of the second pixel area P2 have a flat shape.

The capping layer 175 and the pixel electrode 180 are formed on the first base substrate 101 having the first and second color filters 171 and 172 formed thereon. The supporting member 192 is formed on the first transistor TR1 of the first pixel area P1.

The supporting member 192 is formed in the area of the flat shape so that the gap of the liquid crystal layer 300 may be uniformity maintained. Thus, the quality of liquid crystal filling may be improved.

The filling member 193 formed of the same material as the supporting member 191, fills each of the first, second, third and fourth holes H1, H2, H3 and H4. The holes of the first display substrate 100 are filled with the filling member 193 so that voids in the liquid crystal layer 300 may be prevented. Thus, the quality of liquid crystal filling may be improved.

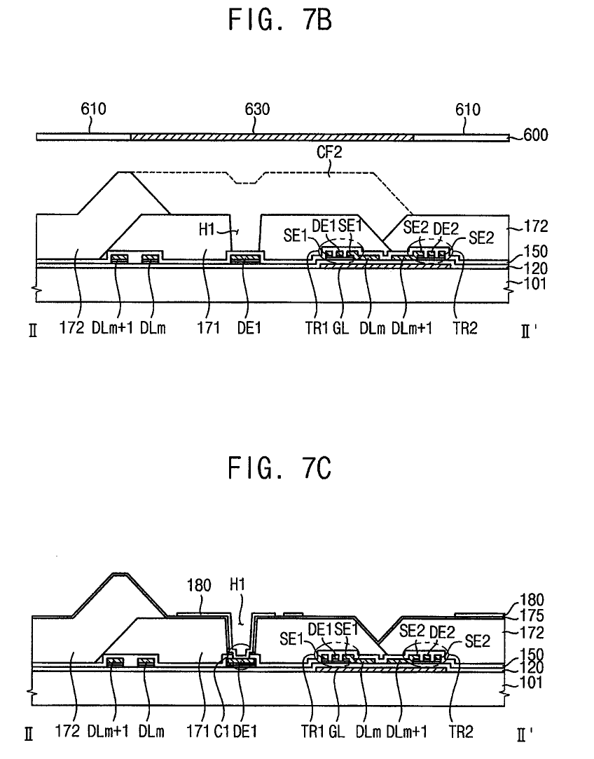

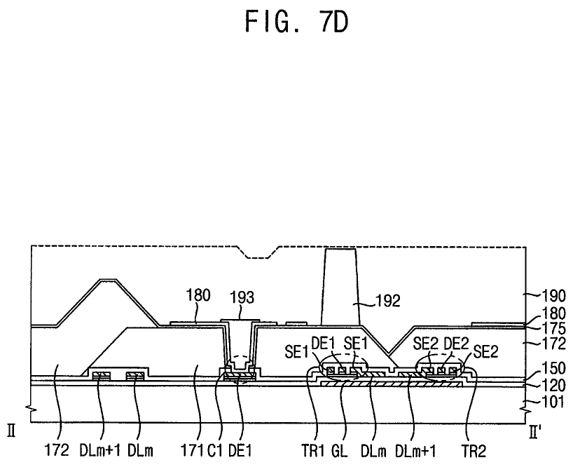

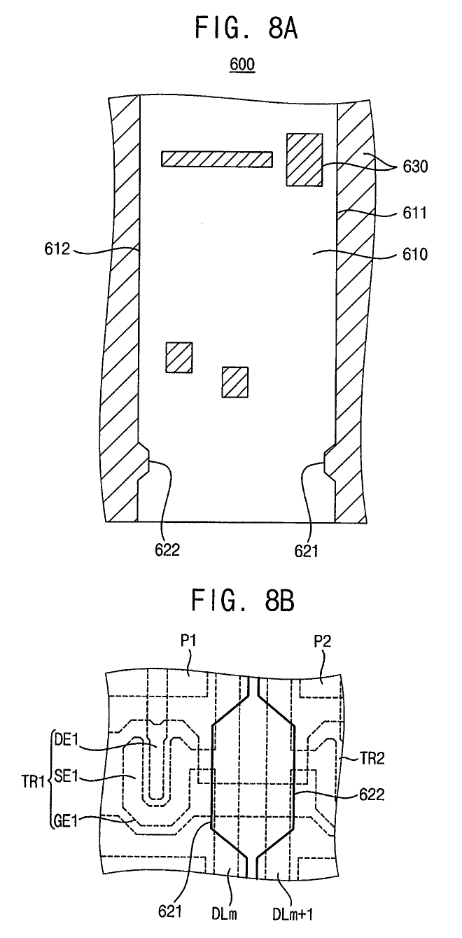

FIGS. 7A to 7D are cross-sectional views illustrating a method for manufacturing the display panel in FIG. 6. FIGS. 8A and 8B are plan views of color filter mask in FIGS. 7A and 7B.

Referring to FIGS. 5, 7A, 8A and 8B, the transistors TR1 and TR2 are formed on the first base substrate 101. The transistors TR1 and TR2 are formed by the same method of manufacturing as the method of manufacturing described referent to FIG. 4A.

A first color filter layer CF1 is formed on the first base substrate 101 having the transistors TR1 and TR2 formed thereon. A color filter mask 600 is disposed on the first base substrate 101 having the first color filter layer CF1.

The color filter mask 600 includes a transmission portion 610 transmitting the light and a blocking portion 630 blocking the light as shown in FIGS. 8A and 8B.

The transmission portion 610 is disposed on the first base substrate 101 corresponding to the pixel area. The transmission portion 610 includes a first straight portion 611, a second straight portion 612, a first recess portion 621 and a second recess portion 622. The first and second straight portions 611 and 612 are extended in the second direction substantially parallel with the data line. The first and second recess portions 621 and 622 are recessed to the transmission portion 610 from the first and second straight portions 611 and 612 corresponding to an area in which the transistor is formed.

For example, the first straight portion exposes the (m)th data line DLm from the light. The recess portion 621 blocks the (m)th data line DLm adjacent to the first transistor TR1 from the light.

The blocking portion 630 is disposed on the first base substrate 101 corresponding to an area over the first color filter layer CF1. As shown, the blocking portion 630 is further disposed on the first base substrate 101 corresponding to areas in which the first contact hole C1, the second contact hole C2 and the storage line SL are formed.

The first color filter layer CF1 is patterned by the color filter mask 600 to form the first color filter 171 on the first pixel area P1. An end of the first color filter 171 patterned by the first straight portion 611 has a slope portion adjacent to the m-th data line DLm, and an end of the first color filter 171 patterned by the first recess portion 621 has a slope portion adjacent to the first transistor TR1 of the first pixel area P1.

The first color filter 171 has the first hole H1 corresponding to the first contact hole C1, the second hole H2 corresponding to the second contact hole C2, the third hole H3 corresponding to the first region of the storage line SL and the fourth hole H4 corresponding to the second region of the storage line SL.

Referring to FIGS. 5, 7B, 8A and 8B, a second color filter layer CF2 is formed on the first base substrate 101 having the first color filter 171 formed thereon.

The color filter mask 600 shifts toward the second pixel area P2. The second color filter layer CF2 is patterned by the color filter mask 600 to form the second color filter 172 on the second pixel area P2.

An end of the second color filter 172 patterned by the second straight portion 612 has a slope portion adjacent to the (m+1)-th data line DLm+1, and an end of the second color filter 172 patterned by the second recess portion 622 has a slope portion adjacent to the second transistor TR2 of the second pixel area P2. The slope portion of the second color filter 172 covers the slope portion of the first color filter 171 to extend to an upper face of the first color filter 171 so that the end of the second color filter 172 is protruded from the upper face of the first color filter 171. Ends of the first and second color filters 171 and 172 adjacent to the first transistor TR1 of the first pixel area P1 are not overlapped with each other by the first and second recess portions 621 and 622 of the color filter mask 600. As shown, the end of the second color filter 172 is not extended to an upper face of the first color filter, and contacts the end of the first color filter 171. The end of the second color filter 172 and the end of the first color filter 171 are formed at substantially the same height.

Therefore, the first color filter 171 is formed to have a flat shape on the first transistor TR1 so that the supporting member 192 may be formed on a flat area. The second color filter 172 also has the first, second, third and fourth holes H1, H2, H3 and H4.

Referring to FIGS. 5 and 7C, the capping layer 175 is formed on the first base substrate 101 having the second color filter 172 formed thereon. The capping layer 175 and the protective layer 150 are etched to form the first and second contact holes C1 and C2.

A transport conductive layer is formed on first base substrate 101 having the first and second contact holes C1 and C2 formed thereon. The transport conductive layer is patterned to form a pixel electrode 180. The pixel electrode 180 includes a first sub-electrode 181 electrically connected to the first transistor TR1 through the first contact hole C1, and a second sub-electrode 182 electrically connected to the second transistor TR2 through the second contact hole C2.

Referring to FIGS. 5 and 7D, a photosensitive organic layer 190 is formed on the first base substrate 101 having the pixel electrode 180 formed thereon. The photosensitive organic layer 190 is patterned to form a supporting member 192 and a filling member 193. In addition, the photosensitive organic layer 190 may be patterned to form a dam member 197a or 197b in the peripheral area PA as shown FIG. 3A or 3B.

The supporting member 192 is formed on the first color filter 171 that is formed to have a flat shape on the first transistor TR1. The filling member 193 fills into the first, second, third and fourth holes H1, H2, H3 and H4 of the first color filter 171.

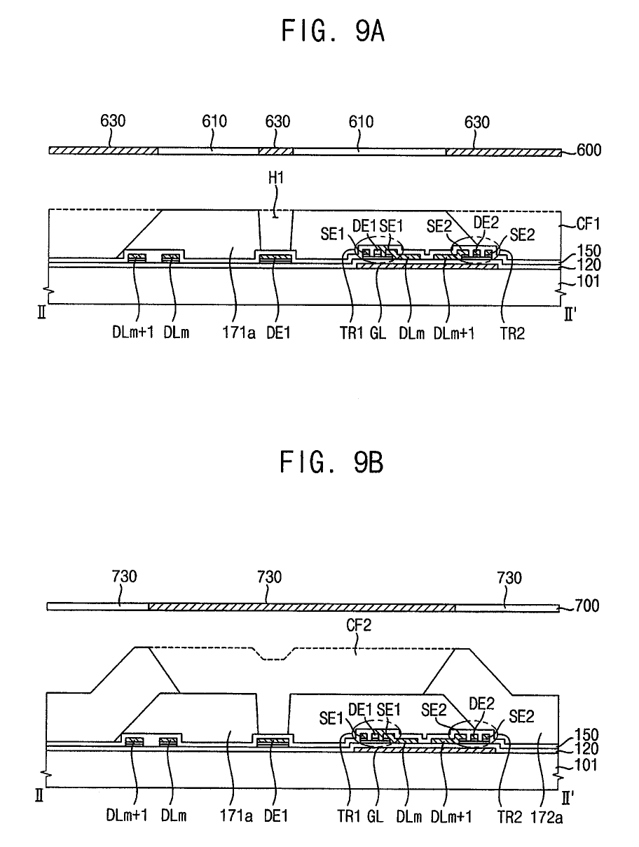

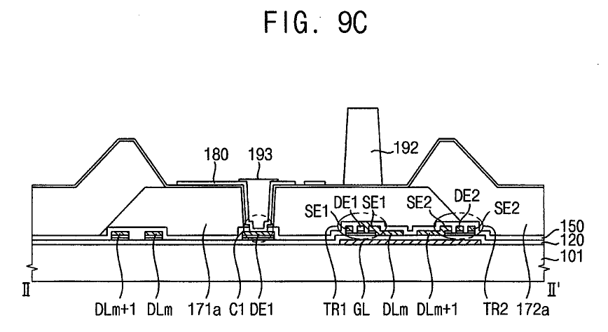

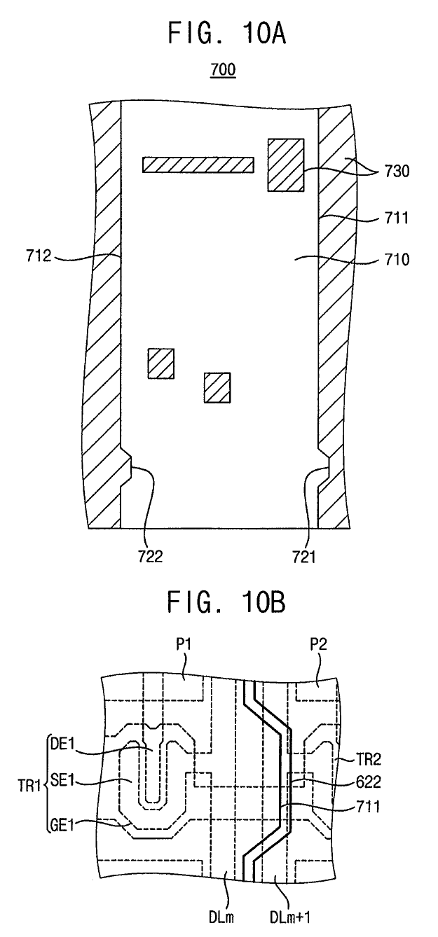

FIGS. 9A to 9C are cross-sectional views illustrating a method for manufacturing a display substrate according to a third embodiment of the present invention. FIGS. 10A and 10B are plan views of color filter mask in FIGS. 9A and 9B.

Referring to FIGS. 5, 9A, 10A and 10B, the transistors TR1 and TR2 are formed on the first base substrate 101. The transistors TR1 and TR2 are formed by the same method of manufacturing as the method of manufacturing described referent to FIG. 4A.

A first color filter layer CF1 is formed on the first base substrate 101 having the transistors TR1 and TR2 formed thereon. A color filter mask 700 is disposed on the first base substrate 101 having the first color filter layer CF1.

The color filter mask 700 includes a transmission portion 710 transmitting the light and a blocking portion 730 blocking the light as shown in FIGS. 10A and 10B.

The transmission portion 710 is disposed on the first base substrate 101 corresponding to the pixel area. For example, the transmission portion 710 includes a first straight portion 711, a second straight portion 712, a protrusion portion 721 and a recess portion 722. The first and second straight portions 711 and 712 are extended in the second direction in which the data line extends. The protrusion portion 721 protrudes to the blacking portion 730 from the first straight portion 711 corresponding to the second transistor TR2 of the second pixel area P2. The recess portion 722 recesses to the transmission portion 710 from the second straight portion 712 corresponding to the second transistor TR2 of the first pixel area P1.

The first straight portion 711 of the transmission portion 710 exposes the (m)th data line DLm from the light. The protrusion portion 721 exposes the (m+1)th data line DLm+1 adjacent to the second transistor TR2 of the second pixel area P2 from the light.

The blocking portion 730 is disposed on the first base substrate 101 corresponding to an area etched the first color filter layer CF1. As shown, the blocking portion 730 is further disposed on the first base substrate 101 corresponding to areas in which the first contact hole C1, the second contact hole C2 and the storage line SL are formed.

The first color filter layer CF1 is patterned by the color filter mask 700 to form the first color filter 171a on the first pixel area P1. An end of the first color filter 171a patterned by the first straight portion 711 has slope portion adjacent to the (m)th data line DLm, and an end of the first color filter 171 a patterned by the protrusion portion 721 has slope portion adjacent to the second transistor TR2 of the second pixel area P2. Thus, the first color filter 171a may be formed to have a flat shape on the first transistor TR1 of the first pixel area P1.

The first color filter 171a has the first hole H1 corresponding to the first contact hole C1, the second hole H2 corresponding to the second contact hole C2, the third hole H3 corresponding to the first region of the storage line SL and the fourth hole H4 corresponding to the second region of the storage line SL.

Referring to FIGS. 5, 9B, 10A and 10B, a second color filter layer CF2 is formed on the first base substrate 101 having the first color filter 171 a formed thereon.

The color filter mask 700 shifts toward the second pixel area P2. The second color filter layer CF2 is patterned by the color filter mask 700 to form the second color filter 172a on the second pixel area P2.

An end of the second color filter 172a patterned by the second straight portion 712 has slope portion adjacent to the (m+1)th data line DLm+1, and an end of the second color filter 172a patterned by the recess portion 722 has slope portion adjacent to the second transistor TR2 of the second pixel area P2.

Ends of the first and second color filters 171a and 172a adjacent to the first transistor TR1 of the first pixel area P1 are not overlapped each other by the protrusion portion 721 and the recess portions 722 of the color filter mask 700. As shown, the end of the first color filter 171 contacts with the end of the second color filter 172. As shown, an overlapping portion of the first and second color filters 171a and 172a is formed on the second transistor TR2 of the second pixel area P2.

Therefore, the first color filter 171a is formed to have a flat shape on the first transistor TR1 so that the supporting member 192 may be formed on a flat area. The second color filter 172a also has the first, second, third and fourth holes H1, H2, H3 and H4.

Referring to FIG. 9C, the capping layer 175 is formed on the first base substrate 101 having the second color filter 172a formed thereon. The capping layer 175 and the protective layer 150 are etched to form the first and second contact holes C1 and C2.

A transport conductive layer is formed on first base substrate 101 having the first and second contact holes C1 and C2 formed thereon. The transport conductive layer is patterned to form a pixel electrode 180. The pixel electrode 180 includes a first sub-electrode 181 electrically connected to the first transistor TR1 through the first contact hole C1, and a second sub-electrode 182 electrically connected to the second transistor TR2 through the second contact hole C2.

A photosensitive organic layer 190 is formed on the first base substrate 101 having the pixel electrode 180 formed thereon. The photosensitive organic layer 190 is patterned to form a supporting member 192 and a filling member 193. In addition, the photosensitive organic layer 190 may be patterned to form the dam member 197a or 197b in the peripheral area PA as shown FIG. 3A or 3B.

The supporting member 192 is formed on the first color filter 171 that is formed to have a flat shape on the first transistor TR1. The filling member 193 fills the first, second, third and fourth holes H1, H2, H3 and H4 of the first and second color filters 171a and 172b.

According to embodiments of the present invention, the supporting member is formed on the first display substrate having the transistor. However the supporting member may be formed on the second display substrate opposing the first display substrate. Also, the dam member formed by the same material as the supporting member may be formed on the peripheral area of the second display substrate.

According to embodiments of the present invention, the filling member fills the holes of the color filter so that the quality of liquid crystal filling may be improved. The supporting member is formed on a flat area so that compression characteristics of the supporting member may be improved. Thus, the quality of liquid crystal filling may be improved. In addition, an empty space of the peripheral area is filled by the dam member to compensate a volume of the liquid crystal layer of the display area, so that the quality of liquid crystal filling may be improved.

Having described the embodiments of the present invention and its advantages, it is noted that various changes, substitutions and alterations can be made herein without departing from the spirit and scope of the invention as defined by the appended claims.

What is claimed is:

1. A display substrate comprising:
a plurality of transistors connected to a plurality of gate lines extending in a first direction on a base substrate and a plurality of data lines extending in a second direction crossing the first direction;
a plurality of color filters disposed over the transistors, and having a plurality of holes;
a plurality of pixel electrodes disposed on the color filters, and electrically connected to the transistors;
a plurality of supporting members disposed on the color filters, and maintaining a gap between the base substrate and a substrate opposing the base substrate; and
a plurality of filling members comprised of the same material as the supporting members, and filling the holes.

2. The display substrate of claim 1, further comprising a dam member comprised of the same material as the supporting members to be disposed in a peripheral area surrounding a display area in which the pixel electrodes are formed, the dam member compensating a volume of a liquid crystal layer dropped on the base substrate.

3. The display substrate of claim 2, wherein the supporting members are disposed on the gate lines.

4. The display substrate of claim 2, further comprising a plurality of dam members having a same shape as each of the supporting members.

5. The display substrate of claim 4, wherein each of the dam members is integrally formed.

6. The display substrate of claim 2, wherein the display area includes a first pixel area disposed on a first color filter, and a second pixel area adjacent to the first pixel area toward the first direction and disposed on a second color filter, and further wherein the first color filter has a flat shape and is formed on the first pixel area in which a first transistor is disposed.

7. The display substrate of claim 6, wherein the supporting member is disposed on the first transistor, and adjacent sides of the first and second color filters form a boundary, wherein the sides are adjacent to the first transistor.

8. The display substrate of claim 6, wherein the supporting member is disposed on the first transistor, and ends of the first and second color filters overlap each other, wherein the ends are disposed in the second pixel area.

9. The display substrate of claim 1, further comprising a storage line, wherein the holes are disposed on areas in which a drain electrode of each of the transistors and the storage line are disposed.

10. The display substrate of claim 1, further comprising a capping layer disposed between the color filters and the pixel electrodes to cover the color filters.

11. A method of manufacturing a display substrate, the method comprising:
forming a plurality of transistors connected to a plurality of gate lines extending in a first direction and a plurality of data lines extending in a second direction crossing the first direction on a base substrate;
forming a plurality of color filters having a plurality of holes on the base substrate having the transistors formed thereon;
forming a plurality of pixel electrodes electrically connected to the transistors on the base substrate having the color filters formed thereon; and
forming a plurality of supporting members and a plurality of filling members on the color filters, the supporting members maintaining a gap between the base substrate and a substrate opposite to the base substrate and the filling members filling the holes.

12. The method of claim 11, further comprising forming a dam member on a peripheral area surrounding a display area in which the pixel electrodes are disposed, wherein the dam member compensates a volume of a liquid crystal layer dropped on the base substrate when the filling members are formed.

13. The method of claim 11, wherein the supporting members are formed on the gate lines.

14. The method of claim 11, wherein forming the color filters includes:
forming a first color filter over a first transistor formed in a first pixel area by using a mask having a transmission portion and a blocking portion, the first color filter having a flat shape; and
forming a second color filter on a second pixel area adjacent to the first pixel area toward the first direction by using the mask.

15. The method of claim 14, wherein the transmission portion of the mask includes a first straight portion extended toward the second direction, a second straight portion substantially in parallel with the first straight portion, a first recess portion recessed toward the transmission portion from the first straight portion and a second recess portion recessed toward the transmission portion from the second straight portion, and
ends of the first and second color filters adjacent to the first transistor contacting each other by the first and second recesses.

16. The method of claim 14, wherein the transmission portion of the mask includes a first straight portion extended toward the second direction, a second straight portion substantially in parallel with the first straight portion, a protrusion portion protruding toward the blocking portion from the first straight portion, and a recess portion recessed toward the transmission portion from the second straight portion, and
ends of the first and second color filters adjacent to the first transistor overlap and an overlapped portion disposed in the second pixel area.

17. The method of claim 11, further comprising forming a storage line when the transistors is formed on the base substrate,
the holes formed on areas in which an end of a drain electrode of each of the transistors and the storage line are disposed.

18. The method of claim 11, further comprising forming a capping layer between the color filters and the pixel electrodes to cover the color filters.

19. A liquid crystal display (LCD) panel having a display substrate comprising:
a first display substrate including;
a plurality of transistors connected to a plurality of gate lines extending in a first direction on a base substrate and a plurality of data lines extending in a second direction crossing the first direction;
a plurality of color filters disposed over the transistors and having a plurality of holes;
a plurality of pixel electrodes disposed on the color filters;
a plurality of supporting members disposed on the color filters; and
a plurality of filling members comprised of the same material as the supporting members filling the holes; and
a second display substrate coupled with the first display substrate to receive a liquid crystal layer, the second display substrate spaced apart from the first display substrate by the supporting member.

20. The LCD panel of claim 19, further comprising a dam member comprised of the same material as the supporting members to be disposed in a peripheral area surrounding a display area in which the pixel electrodes are disposed.
